(19) United States
(12) Patent Application Publication
(10) Pub. No.: US 2005/0193315 A1
(43) Pub. Date: Sep. 1, 2005

(54) Method and apparatus for performing a TFCI reliability check in E-DCH

(76) Inventors: Massimo Bertinelli, Helsinki (FI); Esa Malkamaki, Espoo (FI)

Correspondence Address: WARE FRESSOLA VAN DER SLUYS &;ADOLPHSON, LLP, BRADFORD GREEN BUILDING 5, 755 MAIN STREET, P O BOX 224, MONROE, CT, 06468, US

(21) Appl. No.: 10/782,381

(22) Filed: Feb. 18, 2004

(51) Int. Cl. H03M 13/00

(52) U.S. Cl. 714/758

(57) ABSTRACT

A method (and equipment) for providing additional error detection for at least some signaling bits (such as TFCI bits) in wireless communication between a sending device (20a) and a receiving device (20b) that both use some error detection method (such as a CRC method) to protect bits conveyed over a protected channel—a channel other than the channel over which the signaling bits are conveyed—by including error detection bits with the protected bits, the method characterized by: a step (31 32) in which the sending device computes the error detection bits based not only on the protected bits, but also based on the signaling bits, and transmits the error detection bits so computed with the protected bits and also transmits the signaling bits, but on another channel. The receiving device (20b) then performs a step (33) of detecting errors based not only on the protected bits but also on the transmitted signaling bits.

### TECHNICAL FIELD

The present invention pertains to the field of cellular communication. More particularly, the present invention pertains to wireless communication of data as opposed to voice communication.

### BACKGROUND ART

The present invention concerns the use of a data channel anticipated to be made available in WCDMA (Wideband Code Division Multiple Access) cellular networks—namely E-DCH (Enhanced-Data Channel), an enhanced uplink channel—and provides a form of protection for the so-called Transport Format Combination Indicator (TFCI) needed by a receiver of a WCDMA frame to learn which transport channels are active for the frame. The WCDMA air interface is also referred to as UMTS (Universal Mobile Telecommunications System) terrestrial radio access (UTRA), developed by the third-generation partnership project (3GPP). E-DCH enhances the performance of the uplink compared to Release '99 of WCDMA (Rel99), reducing the delay and possibly increasing the capacity of the system.

The protocol architecture for the WCDMA air interface has three layers: the physical layer (layer one), the (data) link layer (layer two), and the network layer (layer three). The link layer is further divided into RLC (Radio Link Control) and MAC (Medium Access Control). E-DCH is expected to use MAC/L1 (MAC layer one) level retransmissions of packets received with an error (in addition to RLC level retransmissions already specified in Rel99), with soft combining of the different instances at the receiving side to improve the performance, i.e. using a HARQ (hybrid automatic repeat request) process. In order to manage the HARQ process, some kind of reliability check for TFCI is needed.

More specifically, the use by E-DCH of MAC/L1 (H)ARQ allows retransmission of a packet at the MAC/L1 level, with consequent advantages for the system, advantages such as delay reduction and/or increased coverage or capacity. If a packet is received with an error at a Node B (i.e. access point of telecommunications network, sometimes also called a base station or base station component) serving the intended recipient UE (user equipment, i.e. wireless terminal), a retransmission is requested from the transmitting side UE, without involving any higher layer (such as the RLC layer). Good performance can be obtained combining at the receiving side different retransmissions (different versions) of the same packet. In order to perform such recombination, the Node B stores a received transmission in a buffer, and adds to the buffer each retransmission of the same packet. In parallel with the data, so-called outband signaling (control) information is sent in order to make the Node B aware of different parameters needed for the combining. The outband signaling here means signaling bits which are protected separately from the data bits. The outband signaling bits typically have own error detection code as well as channel code (error correction code), whereas so-called inband signaling bits (e.g., a packet header) are typically protected together with the data bits, i.e., with the same error detection and channel codes. Outband signaling bits are typically readable even if there are errors in the data bits whereas inband signaling bits are not readable if there are errors in the data bits. The outband signaling bits/information is better protected than the data itself, because a detected error in the control information means that the data packet must be discarded and because an undetected error in the outband signaling information could corrupt the receiving buffer. Better protection here means a stronger channel code (error correction code), i.e., a lower-rate channel code. The outband signaling information should have error detection capability (and does for downlink, per the prior art, but does not yet have it for uplink), given, e.g., by a CRC (Cyclic Redundant Check) code, in the same way as is already done for the data channel (DCH) in Rel99 of WCDMA. Whatever outband information is implemented, it determines a (power) overhead for the system (and the overhead due to the outband information is important because it can influence the final performance of a link, quite heavily in case of low data rates, and this is true however outband information is actually implemented, time multiplexing it with the data or using a separate code, as in code multiplexing).

The CRC is calculated based on the outband signaling bits and is conveyed on the outband signaling channel as additional bits (e.g., 8, 12 or 16 or even 24 bits, all allowed by Rel99). The totality of the bits conveyed by the outband signaling channel are here called the “outband bits/information,” as distinguished from the phraseology “outband signaling bits/information” used here to indicate only the actual signaling bits, and not also the CRC.

As mentioned, the TFCI is needed by a receiver of a frame to learn which transport channels are active for the frame. More specifically, it is a control field that carries information needed in order to decode the transport channels (e.g. number of transport channel, number of bits per channel, and rate matching parameters). It is actually an index to the transport format combination set and tells the receiving side which transport format combination (TFC) is being used in the current radio frame. TFCI is sent on DPCCH (Dedicated Physical Control CHannel). It has a maximum of 10 information bits, which are encoded using a second-order Reed-Muller code into 32 bits and then punctured down to 30 bits, which are sent on DPCCH at 2 bits per slot (there being 15 slots per 10 ms radio frame). See e.g. 3GPP TS 25.212 for TFCI coding and TS 25.211 for DPCCH details.

The second-order Reed-Muller code is a block code that in principle can be used also for error detection in addition to error correction, at least when not all of the 10 TFCI bits are otherwise in use. (A block code—and so the Reed-Muller code—can be used to detect errors without correcting them, or to both detect and correct a smaller number of errors.) However, if the block code is used for greater error detection, then the error correction capability of the code is reduced and, therefore, typically, the error detection is not fully implemented. For Rel99 this is not a problem: if there is an error in the TFCI, meaning that the receiver tries to decode a wrong transport format combination, then most probably the CRC(s) of the transport channels fail, which means that the transport blocks are discarded. The same would happen if the TFCI error were detected: the transport blocks would be discarded.

So although no error detection capability is provided for TFCI in Rel99 WCDMA systems and none is really needed, not providing error detection for future releases of WCDMA could cause problems, especially in releases where layer one (H)ARQ techniques are adopted. In such releases, an error on TFCI could cause a wrong combination of different transmissions of the same data packet, with the consequent loss of the packet itself and higher level retransmission required (more delay).

An example is illustrated in FIG. 1, where two possible TFCs are considered. In the first one (TFC1), the E-DCH channel, its related outband signaling channel, and a DCH (Rel99) transport channel are present. In the second one (TFC2), there are only the E-DCH and the outband signaling channel. Supposing, for example, that TFC1 is used in a transmission and an error is detected in the E-DCH at the receiving Node B, and so a retransmission of the packet by the UE is requested. Supposing that the UE retransmits the packet using the TFC1 format again. In case of an error in the TFCI, the Node B could (depending on the error) interpret the retransmission as if TFC2 had been used. The Node B would then consider the larger number of channel bits now reserved to E-DCH as an increased redundancy, and decode the data using the channel bits in this way. After that, it would add the data to its buffer containing the previous transmission, but in doing so it would corrupt the buffer since, because of the error in the TFCI, the bits added to the buffer do not correspond in any way to the original ones, but instead are “rubbish” (of no relationship to useful information). Thus, even further retransmissions would not typically help since they would also be combined with this rubbish. At the end of the recombining process, the higher layers would detect the problem and solve it with RLC (Radio Link Controller) retransmissions (as in Rel99), but with a consequent increase in delay compared to the delay that would result in correcting the error at the MAC/L1 layer.

As is known in the art and mentioned above, part of the TFCI channel coding power could be used for error detection. This would, however, reduce the error correction capability of the Reed-Muller code used to encode the TFCI, and so is typically not used. Another possible solution of how to protect the TFCI is to change the TFCI channel coding such that, e.g., a CRC or some other error detection code is added to the TFCI. This would, however, require changes to current TFCI coding and would require more signaling.

Thus, what is needed is a way to protect the TFCI without reducing error correction capability of the Reed-Muller code used in encoding the TFCI, and without requiring more signaling.

### DISCLOSURE OF THE INVENTION

Accordingly, in a first aspect of the invention, a method is provided that gives additional error detection for at least some signaling bits for wireless communication of bits from a sending device to a receiving device, the sending device and the receiving device using a CRC code or some other error detection method to protect bits conveyed over a protected channel by conveying not only the protected bits but also error detection bits, the protected channel being a channel other than the channel over which the signaling bits are conveyed, the method characterized by: a step in which the sending device computes the error detection bits based not only on the protected bits but also based on the signaling bits, and transmits the error detection bits so computed with the protected bits and also transmits the signaling bits, but on another channel.

In accord with the first aspect of the invention, the method may be further characterized by a step in which the receiving device detects errors, based not only on the protected bits but also on the transmitted signaling bits. Further, the method may further comprise a step in which the receiving device discards at least some bits of a frame if an error is detected in the signaling bits, and asks the sending device to retransmit the frame, but does not add to a buffer for soft-combining the discarded bits. Further still, the signaling bits may comprise bits indicating a TFCI for a data channel, and the bits that are discarded in case of detecting an error may be the bits conveyed by the data channel.

Also in accord with the first aspect of the invention, the signaling bits may be conveyed by a control channel used to decode a further channel. Further, the signaling bits may comprise bits indicating a TFCI, and the further channel may be a traffic channel.

Also in accord with the first aspect of the invention, the channel used to convey the signaling bits and the protected channel may both be control channels used to decode a further channel. Further, the signaling bits may convey a TFCI, and the protected channel may be an outband signaling channel. Also further, the protected channel may be time multiplexed with the further channel. Also further, the protected channel may be code multiplexed with the further channel.

Also in accord with the first aspect of the invention, the protected channel may be a traffic channel. Further, the signaling bits may be conveyed by a control channel used to decode a further channel, and the protected channel may be better protected than the further channel.

Also in accord with the first aspect of the invention, the error detection method may involve computing a CRC code value based on the bits to be protected.

In a second aspect of the invention, a computer program product is provided comprising: a computer readable storage structure embodying computer program code thereon for execution by a computer processor in a telecommunication device, with said computer program code characterized in that it includes instructions for performing the steps of a method according to the first aspect of the invention.

In a third aspect of the invention, an apparatus is provided for use by a wireless telecommunications device in providing additional error detection for at least some signaling bits for wireless communication of bits, the device using a CRC code or some other error detection method to protect bits conveyed over a protected channel by conveying not only the protected bits but also error detection bits, the protected channel being a channel other than the channel over which the signaling bits are conveyed, the apparatus characterized by: means by which, when transmitting, the device computes the error detection bits based not only on the protected bits, but also based on the signaling bits, and transmits the error detection bits so computed with the protected bits and also transmits the signaling bits but on another channel.

In accord with the third aspect of the invention, the device may be a UE device, or it may be an access point of a telecommunications network (i.e. e.g. a Node B or a base station or base station component).

Also in accord with the third aspect of the invention, the signaling bits may be conveyed by a control channel used to decode a further channel. Further, the signaling bits may include bits indicating a TFCI, and the further channel may be a traffic channel.

Also in accord with the third aspect of the invention, the channel used to convey the signaling bits and the protected channel may both be control channels used to decode a further channel.

Also in accord with the third aspect of the invention, the signaling bits may convey a TFCI, and the protected channel may be an outband signaling channel. Also further, the protected channel may be time multiplexed with the further channel. Still also further, the protected channel may be code multiplexed with the further channel.

Also in accord with the third aspect of the invention, the protected channel may be a traffic channel. Further, the signaling bits may be conveyed by a control channel used to decode a further channel, and the protected channel may be better protected than the further channel.

Also in accord with the third aspect of the invention, the error detection method may involve computing a CRC code value based on the bits to be protected.

In a fourth aspect of the invention, an apparatus is provided for use by a wireless telecommunications device in providing additional error detection for at least some signaling bits for wireless communication of bits, the device using a CRC code or some other error detection method to protect bits conveyed over a protected channel by conveying not only the protected bits but also error detection bits, the protected channel being a channel other than the channel over which the signaling bits are conveyed, the apparatus characterized by: means by which, when receiving, the device detects errors based not only on the protected bits but also on the transmitted signaling bits.

In accord with the fourth aspect of the invention, the device may be an access point of a telecommunications network, or it may be a UE device.

Also in accord with the fourth aspect of the invention, the apparatus may further comprise means by which when receiving, the device discards at least some bits of a frame if an error is detected in the signaling bits, and requests retransmission of the discarded bits, but does not add the discarded bits to a buffer for soft-combining. Further, the signaling bits may comprise bits indicating a TFCI for a data channel, and the bits that may be discarded in case of detecting an error are the bits conveyed by the data channel.

In a fifth aspect of the invention, a system is provided, comprising a first telecommunications device according to the third aspect of the invention, and also a second telecommunications device.

In a sixth aspect of the invention, a system is provided, comprising a first telecommunications device and also a second telecommunications device according to the fourth aspect of the invention.

### BRIEF DESCRIPTION OF THE DRAWINGS

The above and other objects, features and advantages of the invention will become apparent from a consideration of the subsequent detailed description presented in connection with accompanying drawings, in which:

FIG. 1 is a schematic illustration of two different frames, and indicating a corresponding TFC for each.

FIG. 2 is a block diagram/flow diagram of a sending wireless telecommunication device and a receiving wireless telecommunication device—one e.g. a UE device and the other a Node B—showing components pertinent to the invention.

FIG. 3 is a flow chart illustrating the operation of two communicatively coupled wireless telecommunication devices, according to the invention.

### DETAILED DESCRIPTION OF THE INVENTION

To provide error detection for the TFCI, the invention uses the outband signalling channel already being used to perform HARQ in connection with the E-DCH. As explained above, per Rel99 of WCDMA a CRC (computed at the beginning of the multiplexing and coding chain) is transmitted over the outband signalling channel in order to detect errors in the signalling channel. (E-DCH and outband signaling bits may be either time multiplexed or code multiplexed.) The signalling channel has to be decoded before the data channel (i.e. E-DCH), in order to allow the receiver to perform soft combining for the data (via a HARQ process) in case of errors. The invention exploits the outband CRC to detect possible errors in the TFCI, too, in addition to errors in the outband signaling channel, without increasing the overhead (e.g. by adding new channels) or by increasing complexity (e.g. by adding to the number of bits transmitted). According to the invention, the outband CRC is calculated not only so as to take into account the outband signaling bits, but also the TFCI bits; the receiving side of course does the same in using the received CRC (i.e. in calculating a CRC from the received TFCI and received outband signaling bits and comparing its calculated CRC with the received CRC). If the received CRC indicates an error, the error can be an error in either the outband signaling information or the TFCI, but in any case, according to the invention, the receiving side requests a retransmission, and discards the data packet instead of adding it to the buffer used for soft combining and so corrupting the buffer.

The TCFI parameters (bits) are known when the CRC is computed in the transmitter/sending side. In fact, the transmitter must know the TFCI in order to allocate resources (number of physical channels, channel bits reserved for each transport channel, etc.) needed to communicate the data-being sent over the E-DCH (and possible DCHs). The TFCI is itself sent on a different channel from the data—a control channel, namely DPCCH in Rel99— but the TFCI value is known.

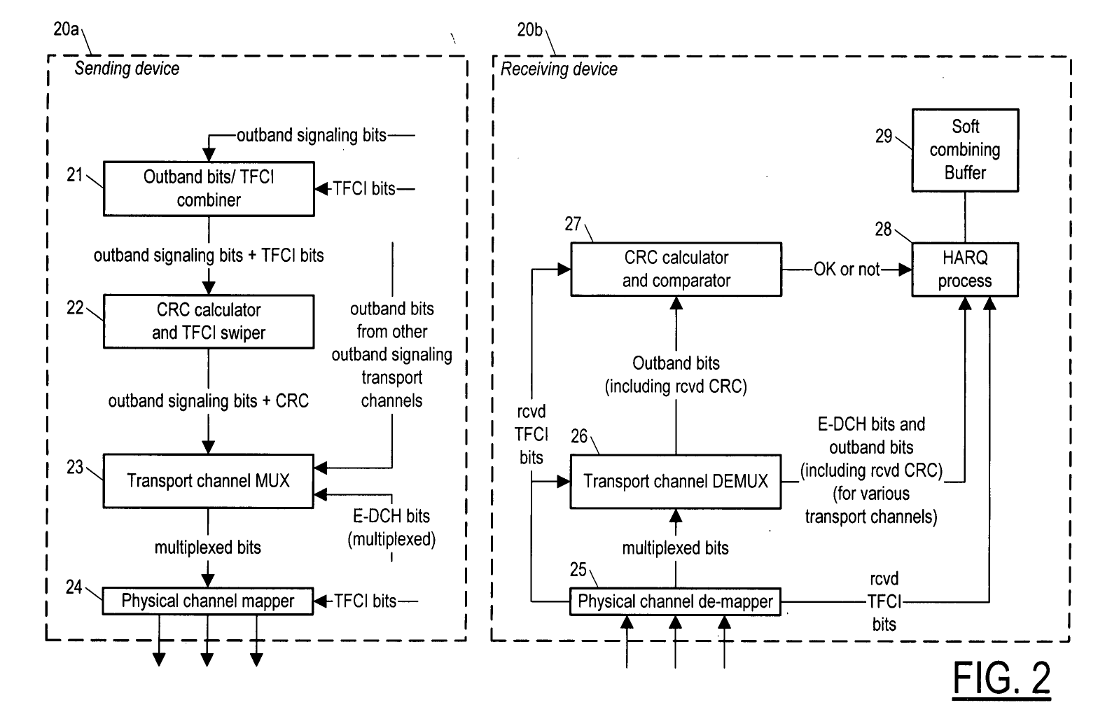

Thus, and referring now to FIG. 2, the invention is shown in terms of a sending wireless telecommunication device 20a, which could be either a user equipment (UE) device or a base station/Node B, i.e. an access point of a wireless telecommunication network, and a receiving wireless telecommunication device 20b, which would be the access point if the sending device 20a is a UE device, and vice versa. (Both the sending device 20a and the receiving device 20b are simplified for clarity—other elements, such as channel coding, rate matching and so on, are not shown for the sake of simplicity.) Although as shown in FIG. 2 and as described below in connection with E-DCH (i.e. for uplink), the sending device 20a includes transmitting equipment according to the invention and the receiving device 20b includes receiving equipment per the invention, both could include both kinds of equipment.

According to the invention, the sending device 20a includes an outband bits/TFCI combiner module 21 that uses as input the TFCI (for the current frame) and the outband signaling bits to calculate a CRC. Then a CRC calculator and TFCI swiper module 22 swipes/removes the TFCI from the bits and adds the calculated CRC (the CRC/outband signaling bits order being irrelevant for the invention). Next, a transport channel MUX (multiplexer) module 23 multiplexes bits from various other data transport channels (as well as possible other outband signaling channels) into a single set of multiplexed bits (segregating the outband signaling bits from the data bits—on E-DCH). The TFCI bits are mapped to the physical channel DPCCH in the physical channel mapper. Finally, a physical channel mapper module 24 maps the multiplexed (data and outband) bits to physical data channels as well as TFCI bits to physical control channel and transmits the bits.

Still referring to FIG. 2, the receiving device 20b, according to the invention, includes a physical channel de-mapper module 25 for extracting multiplexed bits of a current frame from physical channels. TFCI bits are typically extracted in the physical channel de-mapper module and routed from the physical channel de-mapper 25 to the transport channel DEMUX 26 and to the CRC calculator 27. (The TFCI bits are not DEMUXed, but are used for DEMUX operations.) Next, a transport channel DEMUX (de-multiplexer) 26 extracts from the multiplexed bits, the bits for each individual transport channel, but in an operation that differs from a corresponding module according to the prior art, it provides not only the bits for each transport channel, but also provides to a CRC calculator and comparator module 27 the outband signaling bits, the TFCI bits, and the received CRC of the outband channel. The CRC calculator and comparator module 27 then compares the received CRC with a CRC it calculates based on the outband signaling bits and the TFCI bits. If the two CRCs are the same, then the CRC calculator and comparator module 27 signals so to a HARQ process 28, which proceeds as usual, using a soft-combining buffer 29 as needed. (The HARQ process does not normally need the TFCI bits; once the DEMUX is done, the TFCI bits are no longer usually needed, i.e. the outband and E-DCH channels are already separated. Although the TFCI bits are mainly used for TrCH demux, some information is also needed in rate dematching, channel decoding etc., i.e., also in the HARQ processing. Therefore, we show the TFCI bits going to the HARQ process too.)

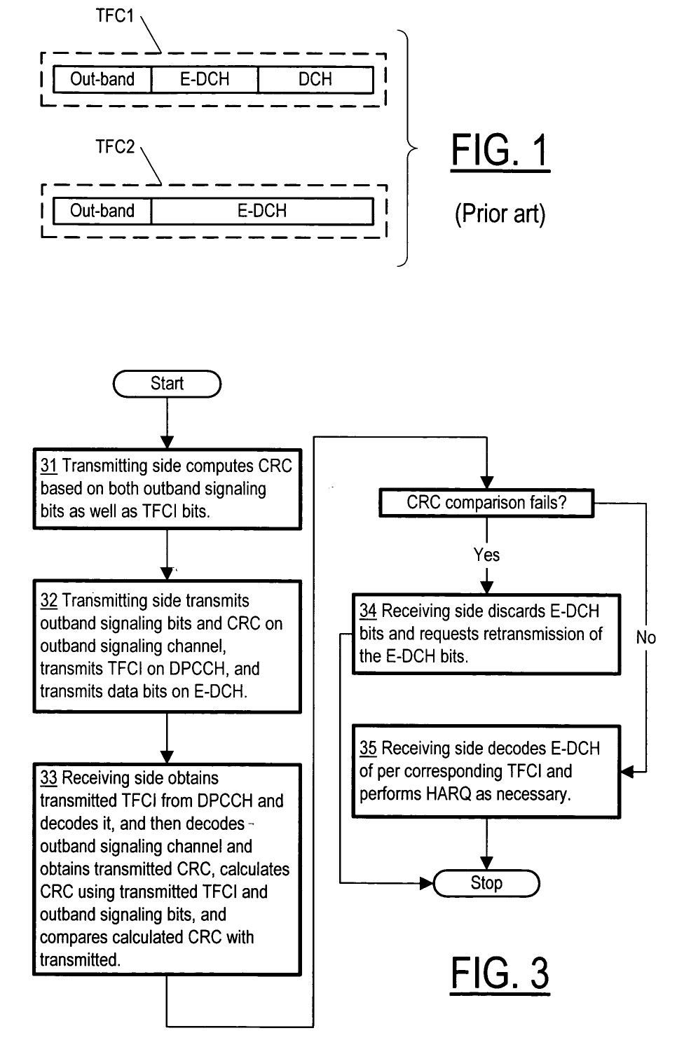

If the two CRCs differ on the other hand, the CRC calculator and comparator 27 signals the HARQ process to discard (typically) the E-DCH bits of the current data frame and request retransmission. (Per the invention, we do not necessarily discard other bits of the current frame, which could include outband bits, E-DCH bits, and possibly DCH bits, as indicated in FIG. 1. The DCH bits are not necessarily discarded if the error is not in the TFCI part and the CRC of the DCH does not fail. The E-DCH bits, however, are typically discarded.)

The CRC computation is done by means of a cyclic generator polynomial, using the TFCI bits and the outband signaling bits as input, i.e. as the blocks of the transport block in order to produce the output of the polynomial. The number of CRC bits attached to a transport block does not depend on the length of the block itself, but is fixed at a predetermined length (signaled by higher layers). It is thus possible to use the TFCI bits together with the outband signaling bits for the sake of CRC computation, without affecting the number of bits being transmitted. The invention thus does not increase the overhead due to the outband signaling channel.

Still referring to FIG. 2, the receiving device 20b decodes the TFCI from the control channel (without any reliability check) and the result is used to decode the transport channels. For transmission using E-DCH, the outband signaling channel has to be processed before the data channel (E-DCH) in order to give to the receiver the information needed to combine possibly different transmissions of the same data block, as explained previously. Once the outband signaling channel has been decoded, the CRC is known and the CRC check is then performed using the received outband signaling bits and the decoded TFCI. Since the CRC takes into account both outband signaling and TFCI bits, the CRC check by the receiving device 20b allows checking not only whether there are errors in the outband signaling bits, but also whether the decoded TFCI was correct or not. An error detected by means of the CRC check indicates that either the outband signaling bits or the TFCI bits (or both) have errors, in which case a retransmission is requested instead of adding the received bits to the buffer for soft combining and so corrupting the buffer (by adding rubbish to the buffer, since the bits determined using a wrong TFCI bear no relationship to the transmitted bits).

Referring now to FIG. 3, the invention is shown as a method including a first step 31, in which the sending side (i.e. the sending device 20a) computes a CRC value based on both outband signaling bits as well as TFCI bits. In a next step 32, the sending side transmits outband signaling bits and the CRC value on the outband signaling channel, transmits the TFCI value on DPCCH, and transmits the data bits on E-DCH. In a next step 33, the receiving side (i.e. the receiving device 20b) obtains the TFCI bits (from DPCCH), then decodes the outband signaling channel and obtains the transmitted CRC value, calculates the CRC using the transmitted TFCI and the outband signaling bits, and then compares the calculated CRC value with the transmitted CRC value. If the CRC check/comparison succeeds, i.e. if the calculated CRC and the transmitted CRC are the same, then in a next step 35 the receiving side decodes E-DCH of the current frame per the corresponding TFCI and performs HARQ as necessary. Otherwise (if the CRC check fails), then in a next step 34 the receiving side discards the E-DCH bits in the current frame and requests their retransmission.

The outband signaling can be sent on a transport channel time-multiplexed with the data channel (E-DCH) as described above. Alternatively, the transport channel carrying outband signaling could be code-multiplexed with the data channel (E-DCH). For instance, separate code channels could be defined for E-DCH(s) and DCH(s). Then the outband signaling channel could be time-multiplexed on either of these code channels, preferably on the same code channel where E-DCH(s) are. Alternatively, the outband signaling can be sent on a separate physical channel (code channel), dedicated for the outband signaling (called for instance E-DPCCH), or the outband signaling could be multiplexed with some other control information and sent on some control channel. As long as there is error detection provided on the outband signaling channel, the TFCI errors can be detected at the same time as described in the present invention.

The DPCCH communicates more than just the TFCI, and as described above, the invention is used to (better) protect the TFCI. As should be clear from the above description, however, the invention can be used to protect more of the DPCCH, and on the other hand, it could be used to protect only part of (only some bits of) the TFCI.

As an alternative to the above mechanism for protecting the TFCI in case outband signaling bits are not transmitted, the TFCI bits can be added to some other transport block of some other transport channel before calculating the CRC for the block. For instance, a voice transport block could be used in place of a outband signaling channel block to convey a CRC for detecting errors in the TFCI and also (in this case) the voice bits, since the protection for the voice channel is typically better than that for the packet data channel. The receiver, after obtaining the TFCI (from some control channel) would first decode the voice channel, and so obtain the transmitted CRC, and then calculate the CRC to compare with the transmitted CRC. If there are errors either in the TFCI part or in the voice part, then the CRC fails and the packet data is not combined with the data in the soft buffer. For the voice channel this would not cause any problem since the voice block would be discarded anyway if either the TFCI or the voice block contained errors.

There are two drawbacks to the alternative: first, the TTI (time transmission interval) length of a voice channel is typically 20 ms, i.e. the CRC is not calculated for every 10 ms radio frame. Second, even if the TFCI were correct for the current frame, errors in the voice channel would force discarding the packet data. With the first embodiment—using the outband signaling channel—these problems do not occur: the TTI of the outband signaling channel is 10 ms or less (typically the same as on the packet data channel) and an error on outband signaling channel automatically forces discarding the packet data.

It should also be clear from what is described above, that the invention is of use not only in case of using CRC-based error detection, but also in case of using any other error detection method. Further, the invention is of use in (better) protecting not only TFCI bits (already protected—at least in some networks—using Reed-Muller), but any bits, although it is of course especially useful in protecting any kind of signaling bits, not simply TFCI bits. Further, in providing better protection for the signaling bits by providing error detection bits on a protected channel based not only on the protected bits of the protected channel but also based on the signaling bits being (better) protected and conveyed by another channel, the signaling bits being protected could be conveyed by a control channel used to decode a further channel, which could be a traffic or any other kind of channel. Also, the channel used to convey the signaling bits and the protected channel could both be control channels used to decode some further channel. Moreover, the protected channel may itself not even be a control channel, but could instead by a traffic channel. Further still, the signaling bits could be conveyed by a control channel used to decode a further channel, and the protected channel could be any channel better protected than the further channel.

As explained above, the invention provides both a method and corresponding equipment consisting of various modules providing the functionality for performing the steps of the method. The modules may be implemented as hardware, or may be implemented as software or firmware for execution by a processor. In particular, in the case of firmware or software, the invention can be provided as a computer program product including a computer readable storage structure embodying computer program code—i.e. the software or firmware—thereon for execution by a computer processor.

It is to be understood that the above-described arrangements are only illustrative of the application of the principles of the present invention. Numerous modifications and alternative arrangements may be devised by those skilled in the art without departing from the scope of the present invention, and the appended claims are intended to cover such modifications and arrangements.

1. A method for use in communicating protected bits from a sending device to a receiving device over a protected channel and also other bits over another channel the method characterized by:
a step (31) in which the sending device computes error detection bits based on both the protected bits and the other bits, and
a step (32) in which the sending device transmits the error detection bits with the protected bits on the protected channel and transmits the other bits on the other channel.

2. A method as in claim 1, further characterized by:
a step (33) in which the receiving device detects errors based on the protected bits and the other bits.

3. A method as in claim 2, further comprising a step (34) in which the receiving device discards at least some bits of a frame if an error is detected in the other bits, and asks the sending device to retransmit the frame, but does not add the discarded bits to a buffer for soft-combining.

4. A method as in claim 3, wherein the other bits comprise bits indicating a TFCI for a data channel, and the bits that are discarded in case of detecting an error are the bits conveyed by the data channel.

5. A method as in claim 1, wherein the other bits are conveyed by a control channel used to decode a further channel.

6. A method as in claim 5, wherein the other bits include bits indicating a TFCI, and the further channel is a traffic channel.

7. A method as in claim 1, wherein the channel used to convey the other bits and the protected channel are both control channels used to decode a further channel.

8. A method as in claim 7, wherein the other bits convey a TFCI, and the protected channel is an outband signaling channel.

9. A method as in claim 7, wherein the protected channel is time multiplexed with the further channel.

10. A method as in claim 7, wherein the protected channel is code multiplexed with the further channel.

11. A method as in claim 1, wherein the protected channel is a traffic channel.

12. A method as in claim 11, wherein the other bits are conveyed by a control channel used to decode a further channel, and the protected channel is better protected than the further channel.

13. A method as in claim 1, wherein the error detection bits are computed using a CRC code.

14. A computer program product comprising: a computer readable storage structure embodying computer program code thereon for execution by a computer processor in a telecommunication device, with said computer program code characterized in that it includes instructions for performing the steps of the method of claim 1.

15. A computer program product comprising: a computer readable storage structure embodying computer program code thereon for execution by a computer processor in a telecommunication device, with said computer program code characterized in that it includes instructions for performing the steps of the method of claim 2.

16. An apparatus for use by a telecommunications device (20a) in communicating protected bits to a receiving device over a protected channel and also other bits over another channel, the apparatus characterized by:
means (21) by which the device (20a) computes error detection bits based on both the protected bits and the other bits, and
means (22) by which the device (20a) transmits the error detection bits with the protected bits on the protected channel and transmits the other bits on the other channel.

17. An apparatus as in claim 16, wherein the device (20a) is a UE device.

18. An apparatus as in claim 16, wherein the device (20a) is an access point of a telecommunications network.

19. An apparatus as in claim 16, wherein the other bits are conveyed by a control channel used to decode a further channel.

20. An apparatus as in claim 19, wherein the other bits include bits indicating a TFCI, and the further channel is a traffic channel.

21. An apparatus as in claim 16, wherein the channel used to convey the other bits and the protected channel are both control channels used to decode a further channel.

22. An apparatus as in claim 21, wherein the other bits convey a TFCI, and the protected channel is an outband signaling channel.

23. An apparatus as in claim 21, wherein the protected channel is time multiplexed with the further channel.

24. An apparatus as in claim 21, wherein the protected channel is code multiplexed with the further channel.

25. An apparatus as in claim 16, wherein the protected channel is a traffic channel.

26. An apparatus as in claim 25, wherein the other bits are conveyed by a control channel used to decode a further channel, and the protected channel is better protected than the further channel.

27. An apparatus as in claim 16, wherein the error detection bits are computed using a CRC code.

28. An apparatus for use by a telecommunications device (20b) in receiving protected bits from a sending device over a protected channel and also other bits over another channel, the apparatus characterized by:
means (25 26) by which the device (20b) receives the protected bits and also the other bits; and
means (27) by which the device (20b) detects errors based on the protected bits but also and on the other bits.

29. An apparatus as in claim 28, wherein the device (20b) is an access point of a telecommunications network.

30. An apparatus as in claim 28, wherein the device (20b) is a UE device.

31. An apparatus as in claim 28, further comprising means (28) by which the device (20b) discards at least some bits of a frame if an error is detected in the other bits, and requests retransmission of the discarded bits, but does not add the discarded bits to a buffer for soft-combining.

32. An apparatus as in claim 31, wherein the other bits comprise bits indicating a TFCI for a data channel, and the bits that are discarded in case of detecting an error are the bits conveyed by the data channel.

33. A system, comprising a first wireless telecommunications device (20a) including an apparatus as in claim 16, and also a second wireless telecommunications device (20b).

34. A system, comprising a first wireless telecommunications device (20a), and further comprising a second wireless telecommunications device (20b) including an apparatus as in claim 28.

35. A method, comprising the steps of:
using both protected symbols for transmission over a protected channel and unprotected symbols for transmission over an unprotected channel in providing error detection symbols for transmission over said protected channel; and
sending said error detection symbols along with said protected symbols on said protected channel and said unprotected symbols on said unprotected channel to a receiver.

36. An apparatus, comprising:
means for providing error detection symbols for transmission over a protected channel using both protected symbols for transmission over the protected channel and unprotected symbols for transmission over an unprotected channel; and
means for sending said error detection symbols along with said protected symbols on said protected channel and said unprotected symbols on said unprotected channel to a receiver.
